(19) United States
(12) Patent Application Publication
(10) Pub. No.: US 2011/0209024 A1
(43) Pub. Date: Aug. 25, 2011

(54) GENERATION DEVICE, CLASSIFICATION METHOD, GENERATION METHOD, AND PROGRAM

(75) Inventors: Meng-Fan Wu, Taipei (TW); Jiun-Lang Huang, Taipei (TW); Xiaoqing Wen, Fukuoka (JP); Kohei Miyase, Fukuoka (JP)

(73) Assignees: KYUSHU INSTITUTE OF TEHNOLOGY, Kitakyushu-shi, Fukuoka (JP); NATIONAL TAIWAN UNIVERSITY, Taipei (TW)

(21) Appl. No.: 13/124,783

(22) PCT Filed: Oct. 5, 2009
(86) PCT No.: PCT/JP2009/067325

§ 371 Date: Apr. 18, 2011

(30) Foreign Application Priority Data
Oct. 23, 2008 (JP) 2008-273484

(51) Int. Cl. G06F 11/00; G01R 31/3183

(52) U.S. Cl. 714/738; 714/E11.02

(57) ABSTRACT

Provided are a generation device and the like for generating a new vector whose volume can be reduced rapidly when an output pattern derived from a decompressor of a logic circuit under test includes an unspecified bit in relation to the logic circuit under test.

The output pattern includes unspecified bits. In step SS1, classification unit classifies the unspecified bits and determines if an unspecified bit is an implied bit or not. The implied bit is an unspecified bit if its value is a logic value determined as logic value 0 or 1 relating to logic bits in the initial vector and according to a predetermined condition (such as compressibility) among bits in the initial vector derived from the upstream logic circuit 1. In step SS1, the unspecified bits which are not implied bits are classified as free bits. The classification unit classifies free bit sets in step SS2, and further classifies free bits to identify compatible free bit sets. The compatible free bits of output pattern can be assigned with logic values independently of each other under the predetermined condition (such as compressibility) in relation to input pattern in step SS3.

### TECHNICAL FIELD

The present invention relates to a generation device, classification method, generation method and program, and particularly relates to a generation device for generating a new vector based on classifying unspecified bits among bits in an initial vector to be applied to a logic circuit or the like.

### BACKGROUND ART

The designers can construct more versatile systems on a chip due to the advanced IC fabrication technology, it also causes new test challenges, for example, the timing related defects and the growing test data volume.

In modern circuits, timing related errors often occur because of the high circuit complexity, the fast clock speed, and the lowered power supply voltage. As a result, delay testing becomes a necessity to ensure high test quality.

The two-pattern test approach is generally accepted for delay testing. The first pattern sets the circuit state and the second pattern activates the desired transition at the fault site. The fault is detected if the transition does not propagate to the target flip-flop(s) within the functional clock period.

FIG. 7 depicts the timing diagram of the launch-on-capture (LOC) at-speed scan testing scheme.

The rising edges of the two capture cycles, C₁ and C₂, correspond to the functional clock cycle, called the launch cycle hereafter. If the transition launched at C₁ does not propagate to the target flip-flop(s) before C₂, the chip under test is classified as faulty.

The LOC scheme suffers yield loss caused by the power supply noise in the launch cycle. Conventional delay fault ATPGs neglect the impact of launch induced switching activity. The generated patterns may cause excessive switching activity in the launch cycle, which leads to abnormally high power network IR-drop and results in extra gate propagation delays. The extra delays may cause a timing-defect-free CUT to fail the delay fault test; this problem is referred to as the power supply noise induced yield loss. For example, in a 130 nm ASIC design performing at 150 MHz clock frequency, some circuits pass the transition fault test only if the supply voltage is above 1.55V; otherwise, they fail.

Previous works that aim at reducing the launch cycle power supply noise can be categorized into the architecture-based class and the pattern-based class. The noise-aware ATPG techniques and the post-ATPG X-filling techniques are pattern-based. Pattern-based techniques are more compatible with any existing design flow and need no circuit modification. Note that X-filling is very powerful whether it is used alone or integrated into ATPG. The reason is that most test patterns, even after compaction, include many X-bits (unspecified bits), which are bits any logic value can be assigned to without deteriorating fault detecting capability; thus, one can properly assign the X-bits to effectively reduce the incurred switching activity.

The work in Non-Patent Document 1 presents a technique called JP-filling. This X-filling technique is both effective and scalable in minimizing launch cycle power supply noise. Given a partially specified test pattern, JP-filling aims at reducing the Hamming distance between the pattern itself and its output response. The result is reduced flip-flop switching activity in the launch cycle, which indirectly brings down the launch cycle WSA.

The JP-filling flow is shown in FIG. 8.

First, in step ST1, it performs 3-valued (0/1/X) logic simulation to derive the output response of the given partially specified pattern. Then, in step ST2, each PPI-PPO pair (pseudo primary input-pseudo primary output pair) is classified as type A, B, C, or D according to the table shown in FIG. 9. These pairs are processed in the order: A, B, and C. (Type D needs no further processing.)

Here, PPI-PPO pair is explained. In general, the manufactured semiconductor logic circuit is mostly a sequential circuit. The sequential circuit comprises a combinational circuit portion including one or a plurality of logic elements such as AND gates, NAND gates, OR gates, NOR gates and the like, and flip-flops for storing internal states of the circuit. Hereupon, the combinational circuit portion comprises an primary input (PI), a pseudo primary input (PPI) which is an output of the flip-flop, an primary output (PO), and a pseudo primary output (PPO) which is an input of the flip-flop. A PPI-PPO pair refers to a pair of a logic value or an unspecified value of a pseudo primary input (PPI) and a logic value or an unspecified value of a pseudo primary output (PPO).

In step ST3, a pair is determined whether it is a type A pair or not. For each type A pair, JP-filling assigns the PPO value to PPI. In step ST4, a pair is determined whether it is a type B pair or not. For each type B pair, it justifies PPO with the specified PPI value. In step ST5, a pair is determined whether it is a type C pair or not. As for the type C pair, the PPI is assigned either 0 or 1 according to probability. Note that all type A pairs are processed at the same time, so do all type B pairs. Type C pairs of which the difference between 0-probability and 1-probability is greater than a pre-defined threshold are also processed at the same time. JP-filling realizes high processing efficiency because pairs are processed at the same time, as described here.

FIG. 9 shows a table of an example of types A, B, C, and D. FIG. 10 gives a JP-filling example. The circled PPO's are the ones that become specified after event-driven simulation.

Among the test challenges of modern circuits, the timing related defects caused by launch noise are described above. In the following, inflation of test data volume is described.

Test data compression has become a necessity as a result of growing test data size in the new generation of technology.

FIG. 11 shows a compactor-decompressor architecture.

A decompressor 53 and a compactor 55 are set for a logic circuit under test 51. Reduced test stimulus is given from ATE 57 to the decompressor 53 and a test pattern with necessary number of bits is given to the logic circuit under test 51. The compactor 55 gives a reduced test response back to ATE 57. That is, the decompressor 53 decompresses the test stimulus from ATE 57 and gives the decompressed output to the logic circuit under test 51. And the compactor 55 reduces the test response from the logic circuit under test 51.

Like launch noise reduction X-filling, test pattern compression techniques properly assigns the X-bits so that the patterns become compressible. That is, it is necessary to assign a proper logic value to X-bits so that the patterns satisfy pluralities of conditions such as launch noise reduction and test pattern compression.

### PRIOR ART DOCUMENTS

### Non-Patent Documents

[Non-Patent Document 1]: X. Wen, K. Miyase, S. Kajihara, T. Suzuki, Y. Yamato, P. Girard, Y. Ohsumi, L.-T. Wang, “A Novel Scheme to Reduce Power Supply Noise for High-Quality At-Speed Scan Testing.,” In Proc. International Test Conference, page 25.1.1-23.1.10, 2007.

### SUMMARY OF THE INVENTION

### Problem to be Solved by the Invention

Since the effectiveness of X-filling based launch noise reduction techniques highly depends on the percentage of X-bits left for assignment, the effect on power supply noise reduction is severely degraded if test pattern compression is performed first. Similarly, applying launch noise reduction X-filling first, in order to give reducing launch noise reduction a dominant position, will sacrifice the data compression capability.

To resolve this problem, there is a need to develop a launch noise reduction technique that is compatible with the utilized test pattern compression scheme if the patterns must satisfy pluralities of conditions such as launch noise reduction and test pattern compression.

In the case where a CMOS circuit constitutes a semiconductor logic circuit, the power consumption includes static power consumption due to leak current and dynamic power consumption due to the switching activity of logic gates and flip-flops. Further; the latter power consumption, which is the dynamic power consumption, includes shift power consumption in a shift operation and capture power consumption in a capture operation. In the case where the semiconductor logic circuit achieves a large scale, ultra-miniaturization and lower power supply voltage, the yield loss induced by the false test is evident. Therefore, it is necessary to reduce the capture power consumption.

Although several previous techniques combine test data compression and test power reduction, they only consider the shift-in induced switching activity and neglect the launch induced switching activity. These techniques solve only the average power issue, which is shift power reduction problem, rather than the instantaneous power supply noise issue which is capture power reduction problem.

That is, an X-filling technique which achieves both high compressibility and high power supply noise reduction has not been proposed.

FIG. 12 shows a provisional flow which is assumed if a JP-filling keeping compressibility is naively aimed. Here, note that the flow shown in FIG. 12 does not constitute a prior art.

Compared to the flow shown in FIG. 8, the flow shown in FIG. 12 further includes a process for determining whether a pattern is compressible or not (step S1) and a process for inverting the logic value assigned to a bit (step S2). Additionally, the flow has the following changes.

First, the multi-bit assignments in JP-filling for type A, B, and C PPI-PPO pairs, which realize high speed processing of JP-filling, are replaced by single-bit assignments. The flow needed this change because assigning logic values to a plurality of X-bits at the same time can lead to loss of compressibility with high possibility. In the prior art, arbitrary logic values can be assigned to a plurality of X-bits because they are assigned directly to X-bits at PPIs for type A pairs or type C pairs.

Second, a compressibility checker examines whether the test pattern is compressible after the single-bit assignment (step S1). If positive, the assignment is accepted; otherwise, the assignment is rejected and the assigned bit is inverted (step S2). Note that the initial test pattern is compressible because it is generated by a compression-aware ATPG. Also, the process of inverting rejected assignments ensures that the test pattern is always compressible.

The above flow shown in FIG. 12 is inefficient because it assigns one X-bit at a time. The flow will call the time-consuming compressibility checker every time a logic value is assigned in the single-bit assignment process, which substantially slows it down.

In the above, the following conditions should be satisfied by utilizing X-bits in a vector applied to the chip of logic circuit under test shown in FIG. 11. One of the conditions is keeping compressibility so that an input vector applied into the decompressor shown in FIG. 11 properly exists. The other is increasing noise reduction rate imposed by the logic circuit under test. However, other conditions may also be set if the conditions can be satisfied by utilizing X-bits and the conditions are imposed on a vector.

It is, therefore, an object of the present invention to provide a generation device or the like for generating a new vector from an initial vector to be applied to a logic circuit based on classifying X-bits among bits in the initial vector, the X-bits being bits whose values are not specified, in order that pluralities of conditions should be simultaneously satisfied, for example, in order that compressibility should be kept with increasing launch noise reduction rate.

### Means for Solving the Problem

A first aspect in accordance with the present invention provides a generation device for generating a new vector from an initial vector to be applied to a logic circuit based on classifying unspecified bits among bits in the initial vector, the unspecified bits being bits whose values are not specified, comprising a first classification unit that classifies an unspecified bit as an implied bit if its value is a logic value determined as logic value 0 or 1 relating to logic bits in the initial vector and according to a predetermined condition among bits in the initial vector, the logic bit being a bit whose value is a specified logic value, and classifies an unspecified bit which is not an implied bit as a free bit, an implied value assignment unit that assigns the logic value determined as 0 or 1 to the implied bit, a second classification unit that classifies the free bits into pluralities of sets, a third classification unit that, when a predetermined set among the pluralities of sets is not empty, further classifies the free bits belonging to the predetermined set as compatible free bits if the predetermined condition is satisfied no matter what logic values are independently assigned to the free bits, and a compatible free bit assignment unit that assigns a logic value 0 or 1 to each compatible free bit, wherein, if there is an unspecified bit in a vector generated after assignment by the implied value assignment unit and by the compatible free bit assignment unit, the first classification unit newly classifies an unspecified bit as an implied bit if its value is determined as logic value 0 or 1 relating to logic bits in the vector generated and according to the predetermined condition, and newly classifies an unspecified bit which is not the implied bit as a free bit.

A second aspect in accordance with the present invention provides a classification method for classifying unspecified bits among bits in an initial vector to be applied to a logic circuit, the unspecified bits being bits whose values are not specified, comprising the step of classifying an unspecified bit as an implied bit if its value is a logic value determined as logic value 0 or 1 relating to logic bits in the initial vector and according to a predetermined condition among bits in the initial vector, the logic bit being a bit whose value is a specified logic value, and classifies an unspecified bit which is not an implied bit as a free bit.

A third aspect in accordance with the present invention provides a classification method for classifying unspecified bits among bits in an initial vector to be applied to a logic circuit, the unspecified bits being bits whose values are not specified, comprising the step of classifying an unspecified bit as an implied bit if its value is a logic value determined as logic value 0 or 1 relating to logic bits in the initial vector and according to a predetermined condition among bits in the initial vector, the logic bit being a bit whose value is a specified logic value.

A fourth aspect in accordance with the present invention provides a classification method for classifying unspecified bits among bits in an initial vector to be applied to a logic circuit, the unspecified bits being bits whose values are not specified, comprising the steps of classifying an unspecified bit as an implied bit if its value is a logic value determined as logic value 0 or 1 relating to logic bits in the initial vector and according to a predetermined condition among bits in the initial vector, the logic bit being a bit whose value is a specified logic value, and classifies an unspecified bit which is not an implied bit as a free bit, and further classifying the free bits as compatible free bits if the free bits belong to a predetermined set where the predetermined condition is satisfied no matter what logic values are independently assigned to the free bits.

A fifth aspect in accordance with the present invention provides a generation method performed by a generation device for generating a new vector from an initial vector to be applied to a logic circuit based on classifying unspecified bits among bits in the initial vector, the unspecified bits being bits whose values are not specified, comprising the steps of classifying an unspecified bit as an implied bit if its value is a logic value determined as logic value 0 or 1 relating to logic bits in the initial vector and according to a predetermined condition among bits in the initial vector, the logic bit being a bit whose value is a specified logic value, and classifies an unspecified bit which is not an implied bit as a free bit, assigning the logic value determined as 0 or 1 to the implied bit, determining whether there is a free bit at a pseudo primary input of a pair of a pseudo primary input and a pseudo primary output (a PPI-PPO pair) or not, and if any, further classifying the free bits at pseudo primary inputs as compatible free bits if the predetermined condition is satisfied no matter what logic values are independently assigned to the free bits at the pseudo primary inputs, and assigning logic values 0 or 1 to the compatible free bits at the same time, newly classifying, if there is an unspecified bit in a vector generated after assignment to the implied bits and to the compatible free bits, an unspecified bit as an implied bit if its value is a logic value further determined as logic value 0 or 1 relating to logic bits in the vector generated and according to the predetermined condition among bits in the vector generated, and newly classifies an unspecified bit which is not an implied bit as a free bit, and assigning the logic value further determined for the newly classified implied bit, determining whether there are newly classified free bits at pseudo primary inputs or not, further classifying the newly classified free bits as newly classified compatible free bits, and assigning logic values to the newly classified compatible free bits.

A sixth aspect in accordance with the present invention provides a program capable of causing a computer to execute the method of any of aspects 2 through 5.

Here, a test vector is an example of a vector. And one or a plurality of vectors constitute a pattern. As for each of the aspects of the present invention, the generation device may include an output pattern memory unit that stores a vector to be applied to a logic circuit, a free pattern memory unit that stores a free pattern after assignment by the implied value assignment unit, a logic pattern memory unit that stores a logic pattern after assignments by the implied value assignment unit and by the compatible free bit assignment unit, or a bit classification memory unit that stores information relating to bits in a test pattern, for example, information of which bit is a logic bit, an unspecified bit, an implied bit, or a free bit and which bit set is a compatible free bit set. And classification units or the like may perform the processes referring to the memory units listed above.

In the first and the fifth aspect of the present invention, the generation device or the generation method may perform, or may include the step of performing, not only the second time of classification and assignment processes for the vector obtained from the first time of classification and assignment processes but also the third time or more.

### Effect of the Invention

According to the present invention, it is made possible to classify unspecified bits into implied bits and free bits. An implied bit is an X-bit whose value is a logic value determined in order to satisfy a predetermined condition relating to logic bits in the initial vector (“first condition”). A free bit is an X-bit which is not an implied bit. Therefore, first condition and another condition (“second condition”) can be simultaneously satisfied by assigning necessary logic values to the free bits.

Besides, according to the present invention, it is also made possible to further classify the free bits, which can be unspecified bits in order to satisfy the first condition, to identify compatible free bits. Compatible free bits are free bits to which logic values can be assigned independently of one another in order to satisfy the first condition. Therefore, it is made possible to identify compatible free bits to which logic values can be simultaneously assigned. And by simultaneously assigning, faster processing can be achieved than that of a provisional flow in FIG. 12, with keeping compressibility of the initial vector.

Further, according to the first and the fifth aspects of the present invention, it is also made possible to generate a new vector which simultaneously satisfies the first condition and the second condition, through fast processing.

Therefore, an efficient compression-compatible JP-filling is developed to generate compressible patterns with low launch cycle supply noise. The proposed technique has been validated with the ISCAS' 89, ITC'99, and one industrial design. Without sacrificing fault coverage and the test set compressibility, which corresponds to the first condition, the proposed technique reduces the launch cycle WSA (weighted switching activity), which corresponds to the second condition, by 26% for the largest circuits and 17% for all the circuits in average.

A fault list shuffling mechanism can be introduced to help escape from the local optima. This procedure is very effective for the large industry circuit.

### BRIEF DESCRIPTION OF THE DRAWINGS

FIG. 1 illustrates a flowchart showing the generation method of an output pattern in accordance with an embodiment of the present invention.

FIG. 2 shows a schematic block diagram of an information processor in accordance with an embodiment of the present invention for classifying bits in an output pattern and assigning logic values.

FIG. 3 illustrates the CSNR-Test flow.

FIG. 4 depicts the flow showing the detail of the compressible supply noise reduced ATPG (step SST5) in FIG. 3.

FIG. 5 depicts the CJP-filling flow in accordance with the embodiment of the present invention.

FIG. 6 illustrates an example flow of identifying a compatible-free-bit-set from a test vector by CJP-filling in accordance with the present invention.

FIG. 7 depicts the timing diagram of the launch-on-capture (LOC) at-speed scan testing scheme.

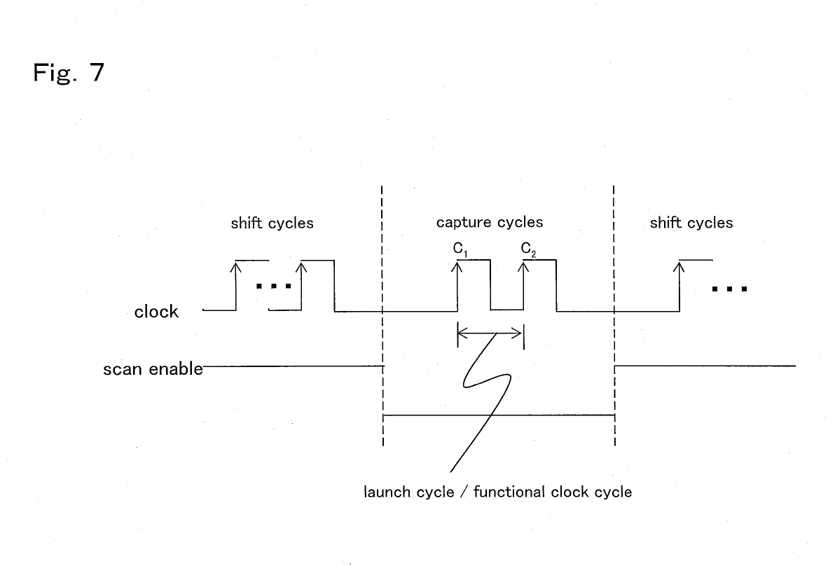

FIG. 8 shows a JP-filling flow.

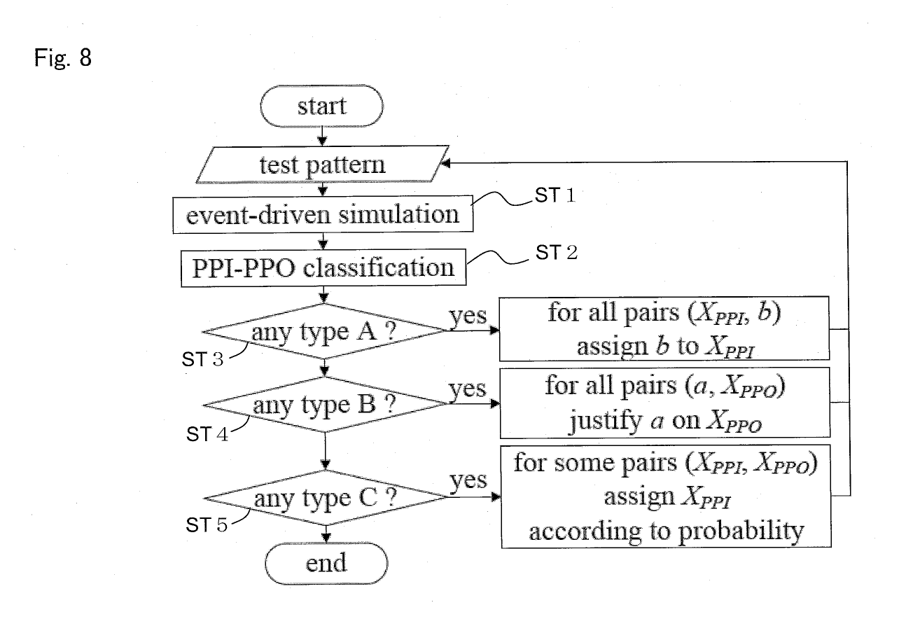

FIG. 9 shows a table of an example of types A, B, C, and D.

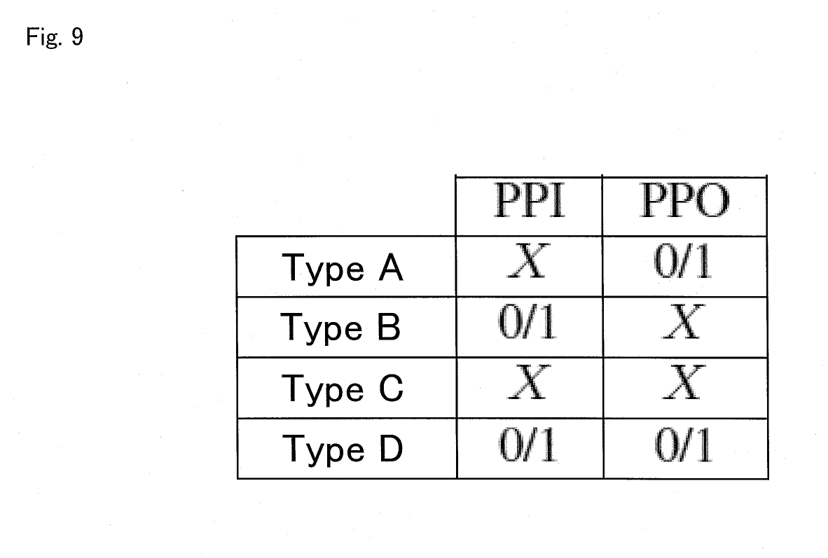

FIG. 10 shows a JP-filling example.

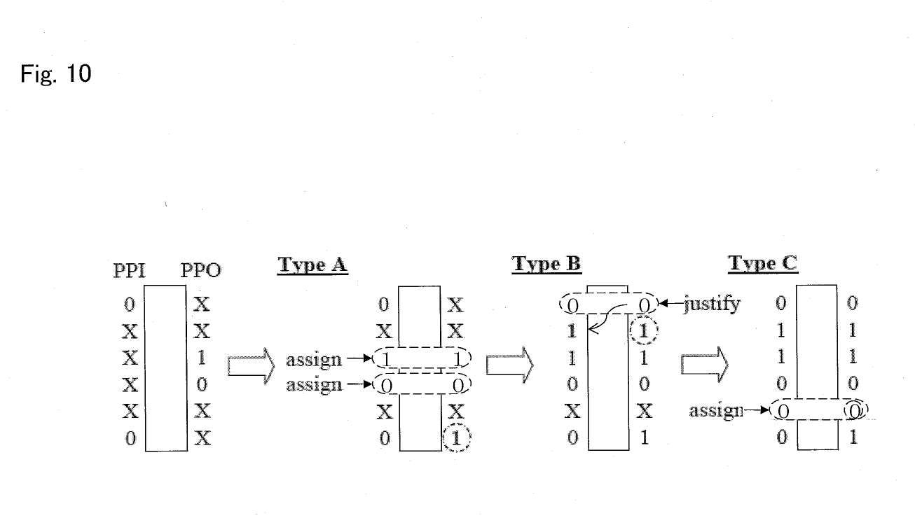

FIG. 11 shows a compactor-decompressor architecture.

FIG. 12 shows a provisional flow which is assumed if a JP-filling keeping compressibility is naively aimed. This flow does not constitute a prior art.

### MODES FOR CARRYING OUT THE INVENTION

Here, the linear-decompressor-based scheme is focused. Compared to the code-based and broadcast-scan-based schemes, it has the advantages of high compression rate and very little hardware overhead. Furthermore, it has been widely adopted in industry designs.

The proposed technique is called as “Compressible Supply Noise Reduced Test” and hereinafter referred to as CSNR-Test for short. Before describing further details of CSNR-Test, the concepts of implied and free X-bits are introduced and show how to determine whether an X-bit is a free or implied one.

Definition 1. An X-bit in a compressible pattern is 0(1)-compressible if the resulting pattern is compressible after the X-bit is assigned 0(1).

Definition 2. An X-bit in a compressible pattern is a free-bit if it is both 0-compressible and 1-compressible.

Definition 3. An X-bit in a compressible pattern is an implied-bit if it is either 0-compressible or 1-compressible, but not both.

Definition 4. The implied-value of a 0-compressible implied bit is 0; the implied-value of a 1-compressible implied bit is 1.

Definition 5. A partially specified pattern is a free pattern if all its X-bits are free bits.

The following example depicts the difference between free and implied bits. Consider the following linear system.

$$[ \begin{matrix}1 & 1 & 1 & 0 \\ 1 & 0 & 1 & 0 \\ 1 & 0 & 0 & 1 \\ 0 & 1 & 1 & 1\end{matrix} ] \cdot [ \begin{matrix}{y}_{1} \\ {y}_{2} \\ {y}_{3} \\ {y}_{4}\end{matrix} ] = [ \begin{matrix}{z}_{1} \\ {z}_{2} \\ {z}_{3} \\ {z}_{4}\end{matrix} ] = [ \begin{matrix}X \\ X \\ 1 \\ 0\end{matrix} ] \qquad Formula 1$$

In this example, z₃ and z₄ have been specified as 1 and 0, respectively. The corresponding linear equations are as follows.

y₁+y₂+y₃=z₁ (1)

y₁+y₃=z₂ (2)

y₁+y₄=1 (3)

y₂+y₃+y₄=0 (4)

From the equations (1), (3) and (4), the following formulas are obtained. Here, 0+1=1, 0+0=0, 1+1=0 are applied because these are the calculations of exclusive OR or EXOR. Concretely, y₄+y₄=0 is used in the deformation from equation (5) to (6).

$$\begin{matrix}{z}_{1} = {y}_{1} + {y}_{2} + {y}_{3} & ( 5 ) \\ = ( {y}_{1} + {y}_{4} ) + ( {y}_{2} + {y}_{3} + {y}_{4} ) & ( 6 ) \\ = 1 + 0 & ( 7 ) \\ = 1 & ( 8 )\end{matrix}$$

The equations above show that z₁'s value has been implied by the specified z₃ and z₄ even though we have not explicitly specified it. From the M matrix's point of view, one can arrive at (8) because z₁'s row vector, the first row vector in M, can be spanned by those of z₃ and z₄. According to the definition, z₁ is a 1-compressible implied bit. On the contrary, we cannot find any linear combination of (3) and (4) to arrive at (2), i.e., the row vector of z₂ cannot be spanned by those of z₃ and z₄. z₂ can be assigned either 0 or 1. Thus, it is 0-compressible and 1-compressible, and by definition, a free bit.

Theorem 1. Given a compressible test pattern V, if the row vector of an X-bit can be spanned by the row vectors of the specified bits, the X-bit is an implied-bit; otherwise, it is a free-bit.

Proof. If the row vector of an X-bit can be spanned by some of the row vectors of the specified bits, the value of this X-bit can be computed in the same way as we compute z₁ in the above example. Thus, this X-bit is an implied one.

Now, let's prove the other half of the theorem. Since the pattern is compressible, we have

Rank([Mₛ|Vₛ])=Rank(Mₛ)=r. (9)

Consider an X bit whose row vector cannot be spanned by Mₛ. Let's add its row vector to Mₛ and denote the resulting matrix by Mₛ′. The rank of Mₛ′ is r+1. As a result, the corresponding augmented matrix will also have a rank of r+1 no matter this X bit is assigned 0 or 1. Thus, by definition, this X bit is a free bit. Q.E.D.

Lemma Given a compressible test pattern V, assigning an implied bit with its implied-value does not affect the compressibility of the test pattern.

Proof. Assume that Rank ([Mₛ|Vₛ])=rbefore the assignment. Since the assigned X-bit is an implied one, we have Rank (Mₛ′)=r where Mₛ′ is as defined in Theorem 1. The way the implied value is computed ensures that Rank ([Mₛ′|Vₛ′])=r, where Vₛ′ is the resulting pattern after the assignment. This proves the lemma. Q.E.D.

One way to determine whether an X-bit is free or implied is as follows.

1. Compute the orthogonal basis of Mₛ and denote by B the set of row vectors in the orthogonal basis.

2. Check whether the X-bit's row vector can be spanned by B or not. If positive, the X-bit is implied; otherwise, it is free.

Note that a free bit may become an implied one after some other free bits are specified. Thus, one should execute X-bits classification process after each X assignment.

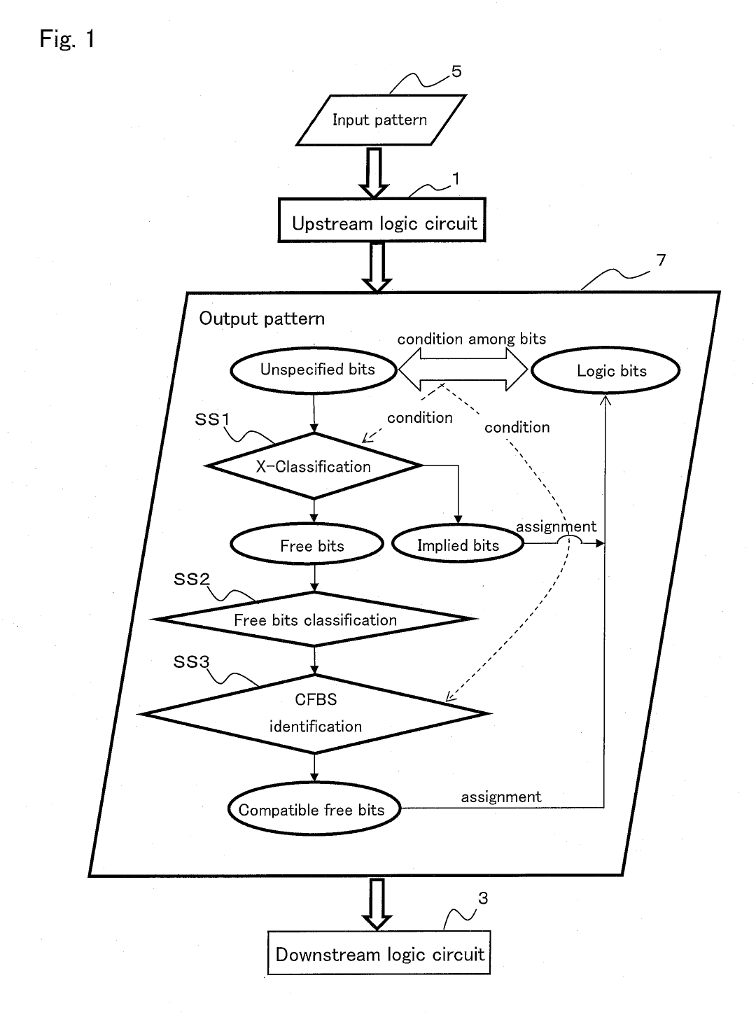

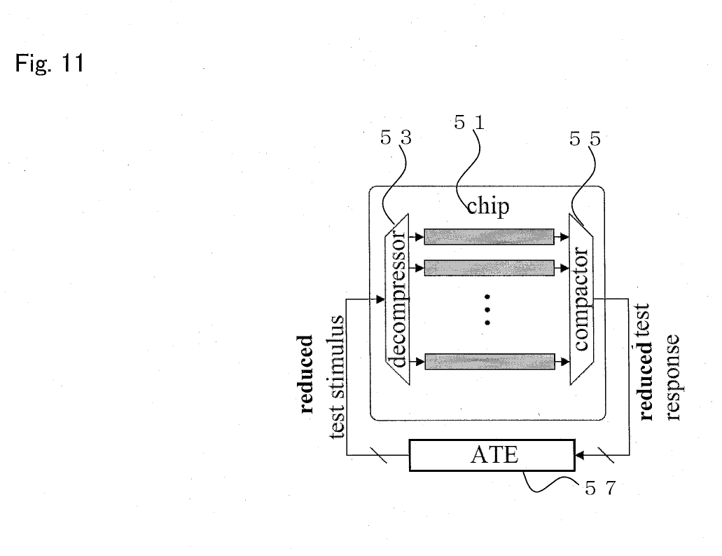

FIG. 1 illustrates a flowchart showing the generation method of an output pattern (an example of “initial vector” described in CLAIMS) in accordance with an embodiment of the present invention. Hereinafter, the logic circuit of the decompressor 53 is an example of “upstream logic circuit” and the logic circuit under test shown in FIG. 11 is an example of “downstream logic circuit.” The output pattern from the upstream logic circuit is the input pattern into the downstream logic circuit. And hereinafter, “input pattern” and “output pattern” refer to the input pattern and the output pattern of the upstream logic circuit, respectively, unless there are other explanatory notes.

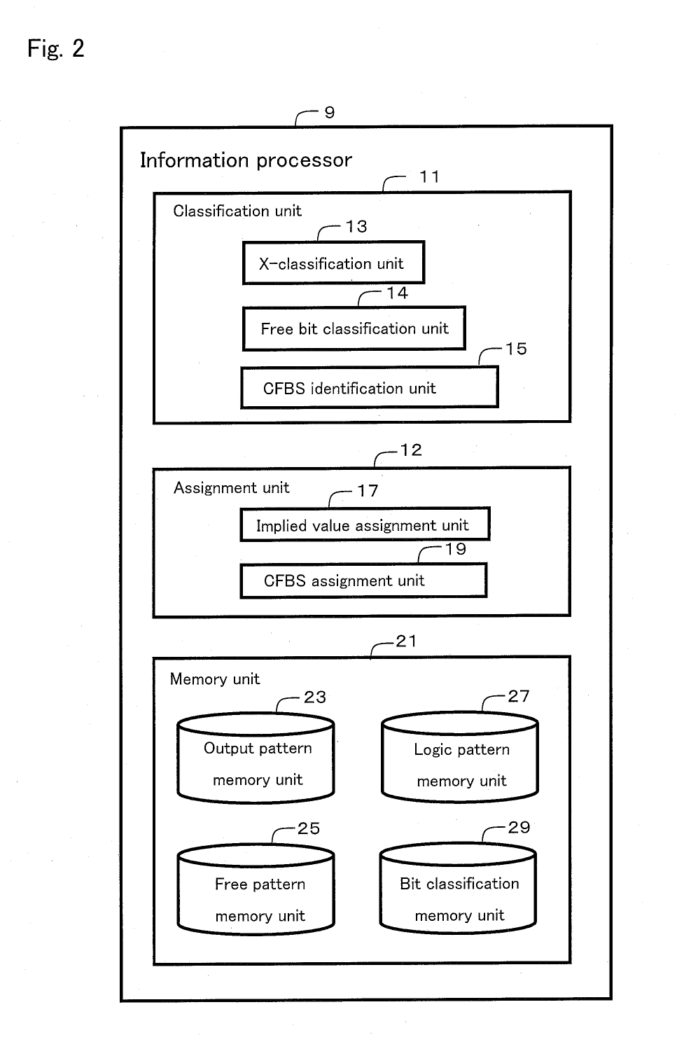

FIG. 2 shows a schematic block diagram of an information processor in accordance with an embodiment of the present invention for classifying bits in an output pattern and assigning logic values. The information processor 9 includes a classification unit 11, an assignment unit 12, and a memory unit 21. The classification unit 11 classifies unspecified bits in the output pattern. The assignment unit 12 assigns logic values to unspecified bits. The memory unit 21 stores vectors and information of bits in the vectors. The classification unit 11 includes an X-classification unit 13 (an example of “first classification unit” described in CLAIMS), a free bit classification unit 14 (an example of “second classification unit” described in CLAIMS), and a CFBS identification unit 15 (an example of “third classification unit” described in CLAIMS). The X-classification unit 13 classifies unspecified bits in the output pattern into implied bits and free bits. The free bit classification unit 14 classifies free bits according to PPI-PPO pairs. The CFBS identification unit 15 identifies compatible free bit sets among the free bits. The assignment unit 12 includes an implied value assignment unit 17 (an example of “implied value assignment unit” described in CLAIMS) and a CFBS assignment unit 19 (an example of “compatible free bit assignment unit” described in CLAIMS). The implied value assignment unit 17 assigns logic values to implied bits. The CFBS assignment unit 19 assigns logic values to compatible free bits. The memory unit 21 includes an output pattern memory unit 23, a free pattern memory unit 25, a logic pattern memory unit 27, and a bit classification memory unit 29. The output pattern memory unit 23 stores the given output patterns 7. The free pattern memory unit 25 stores free patterns. The logic pattern memory unit 27 stores logic patterns, where all the bits are specified. The bit classification memory unit 29 stores information of bits in the test patterns such as information which bits are logic bits, unspecified bits, implied bits, or free bits, or which bit sets are compatible free bit sets.

Comparing FIGS. 1 and 2 with the compactor-decompressor architecture shown in FIG. 11, the upstream logic circuit 1 corresponds to the decompressor 53 and the downstream logic circuit 3 corresponds to the compactor 55. The input pattern 5 is applied to the upstream logic circuit 1. The upstream logic circuit 1 performs, for example, bit decompression and outputs an output pattern 7. The output pattern 7 is applied to the downstream logic circuit 3 as an input pattern such as an initial test vector.

The output pattern 7 is processed as follows. The output pattern 7 is stored in the output pattern memory unit 23. The output pattern 7 includes unspecified bits in relation to the downstream logic circuit 3 (such as fault detection.) If the downstream logic circuit 3 is a logic circuit under test, the output pattern is called as a test cube. In step SS1, X-classification unit 13 of the classification unit 11 in the information processor 9 classifies the unspecified bits and determines if an unspecified bit is an implied bit or not. The implied bit is an unspecified bit if its value is a logic value determined as logic value 0 or 1 relating to logic bits in the initial vector and according to a predetermined condition among bits in the initial vector derived from the upstream logic circuit 1. In step SS1, the unspecified bits which are not implied bits are classified as free bits. The bit classification memory unit 29 stores which bits are implied bits or free bits.

In this embodiment, free bits are unspecified bits which can be 0 or 1 in the output pattern 7 in order to satisfy a condition imposed based on the relation between the output pattern 7 and the downstream logic circuit 3 (such as fault detection) as well as in order to satisfy another predetermined condition imposed based on the relation between logic bits in the vector derived from the upstream logic circuit 1.

In step SS2, the free bit classification unit 14 classifies free bits into pluralities of sets according to PPI-PPO pairs. In step SS3, the CFBS identification unit 15 of the classification unit 11 classifies some of the classified free bits in the output pattern 7 to identify compatible free bits. The compatible free bits can be assigned with logic values independently of each other under the predetermined condition (such as compressibility) imposed based on the relation between logic bits in the vector derived from the upstream logic circuit 1. The bit classification memory unit 29 stores which bits are compatible free bit sets.

Here, implied bits are made into logic bits after the assignment by the implied value assignment unit 17. And compatible free bits are made into logic bits after the assignment by the CFBS assignment unit 19. The free pattern memory unit 25 stores free patterns, where all the implied bits are assigned with their implied values. If an unspecified bit remains in a vector after these assignments, step SS1 through SS3 are repeated. The logic pattern memory unit 27 stores logic patterns, where all the unspecified bits are assigned.

The more detail is described below.

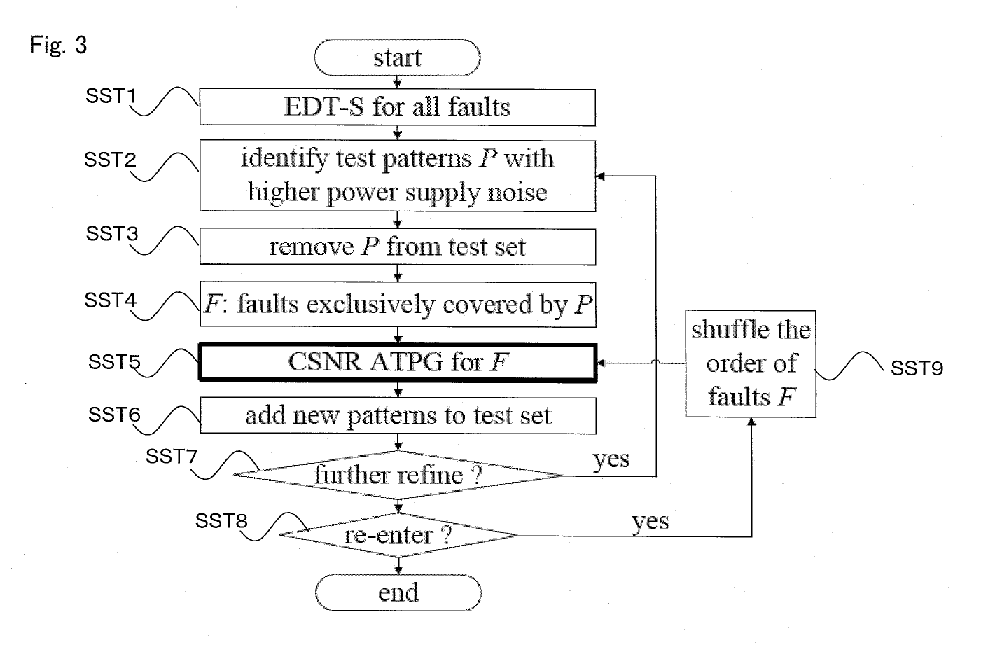

The CSNR-Test flow is depicted in FIG. 3.

First, an ATPG that generates compressible at-speed test patterns, e.g., the EDT-Standard, is utilized to obtain the initial compressible test set (step SST1). CSNR-Test then enters the test set refinement process to lower the launch cycle supply noise (step SST2 or thereafter). In each refinement iteration, the set of patterns whose launch cycle WSA is greater than 99% of the maximum launch cycle WSA in the current test set are identified (steps SST2 to SST 7). These patterns form the set of high supply noise patterns, denoted by P, that is to be refined. The threshold is set to 99% so that the maximum launch cycle WSA is reduced by at least 1% in each iteration.

Once identified, P is removed from the test set (step SST3) and fault simulation is performed to identify the set of faults F that are exclusively detected by P (step SST4). A launch cycle noise-aware ATPG targets the faults in F (step SST5). If the newly generated patterns improve the maximum launch cycle WSA, they are accepted; otherwise, they are rejected (steps SST6 to SST8). In the latter case, CSNR-Test randomly shuffles the order of faults in F and re-enters the refinement process (step SST9). These shuffles prevent CSNR-Test from being trapped in local optima. If CSNR-Test fails to improve the maximum launch cycle WSA for 5 consecutive iterations, i.e., 5 continuous shuffles, it terminates the refinement process. In our experiments, if more continuous shuffles are allowed, substantial improvement is observed for the 3 largest circuits.

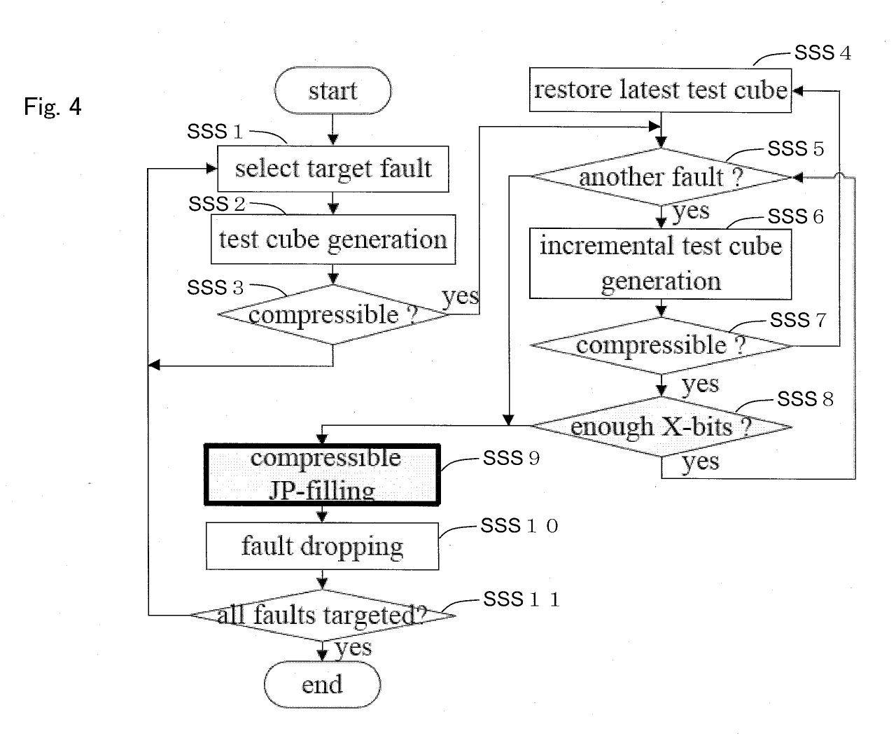

FIG. 4 depicts the flow showing the detail of the compressible supply noise reduced ATPG (step SST5) in FIG. 3.

The flow is a modified version of the EDT-Standard. The modified steps are described below. Steps SSS8 and SSS9 indicate the augmented steps, including the new dynamic compaction constraint and the compressible JP-filling-the former (step SSS8) ensures that the generated patterns still have enough X-bits left; the latter (step SSS9) performs the compressible low launch noise X assignments. One side effect of the added dynamic compaction constraint is the increased test set size. However, because CSNR-ATPG only targets the faults that are exclusively detected by high noise patterns, there is no significant test set size increase in the experimental results.

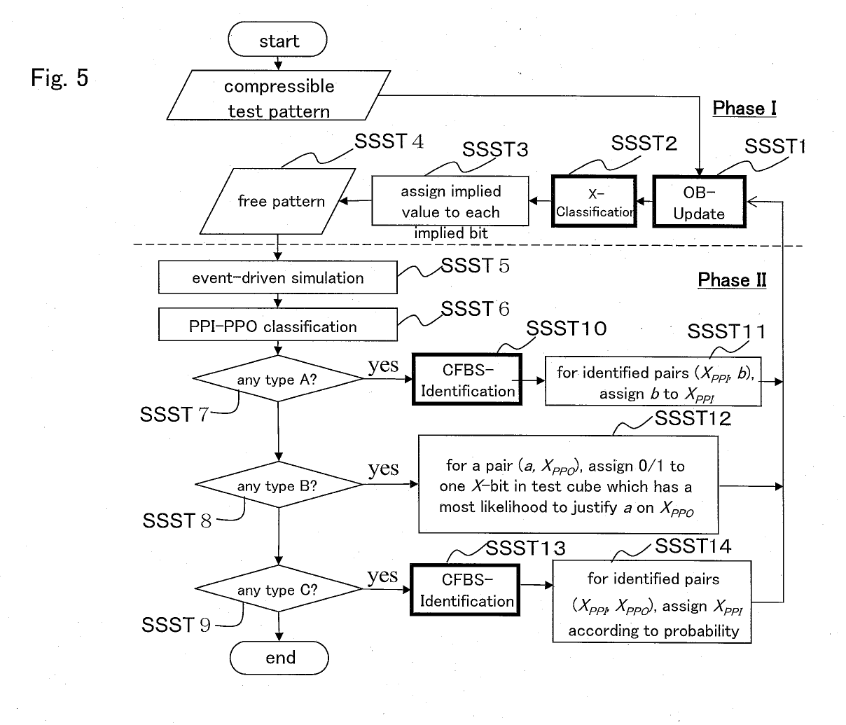

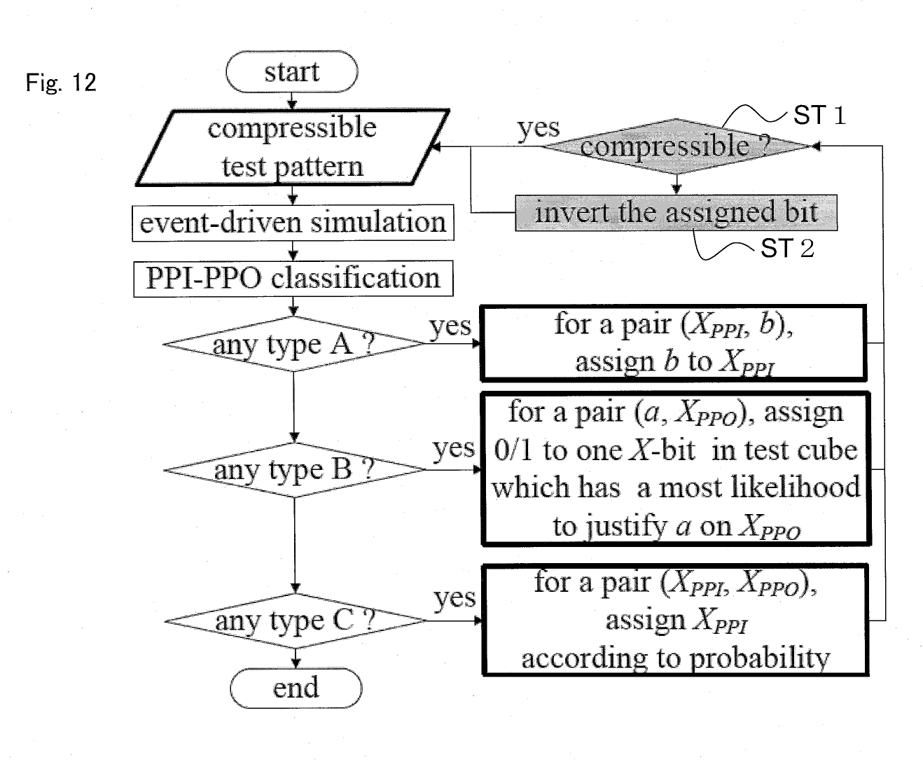

The compressible JP-filling (CJP-filling), whose concept is shown in FIG. 1, is the core technology of CSNR-ATPG. It tightly integrates launch cycle noise reduction and test pattern compression. The detail explanation is described below referring to FIG. 5. Compared to the approach shown in FIG. 12, the proposed CJP-filling shown in FIG. 5 substantially improves the CPU time by enabling multi-bit assignments (for type A and type C pairs) and by avoiding making unnecessary assignments on the implied bits.

FIG. 5 illustrates the flow showing CJP-filling in accordance with the embodiment of the present invention.

The flow can be divided into two phases. The upper part constitutes Phase I which keeps the pattern free. The lower part constitutes Phase II which makes compressible launch noise reduction assignments. The loop is repeated until the pattern is fully specified.

In Phase I, we first derive or update the orthogonal basis associated with the current pattern (“OB Update”), from ATPG or Phase II (step SSST1). Based on the updated orthogonal basis, the X-bits are classified as implied or free in “X-Classification” (step SSST2). All the implied bits are as signed with their respective implied values (step SSST3); these assignments must be compressible according to Lemma. The process of identifying and assigning the implied bits in Phase I prevents CJP-filling from making unnecessary or unacceptable assignments in Phase II (step SSST4). This substantially reduces the number of times the loop is executed and thus improves the CJP-filling efficiency.

In Phase. II, event-driven simulation is first performed (step SSST5) to derive the output response of the current pattern. Then, PPI-PPO pairs are classified (step SSST6) and they are processed in the following ways.

A PPI-PPO pair is determined whether it is Type A (X, 0/1) or not in step SSST7, whether it is Type B (0/1, X) or not in step SSST8, and whether it is Type C (X, X) or not in step SSST9.

For Type A, we first perform compatible-free-bit-set identification (CFBS Identification) which identifies a set of X-bits that can be arbitrarily assigned at the same time without affecting the compressibility (step SSST10). Then, the original JP-filling method is utilized to assign these X-bits (step SSST11); the resulting pattern is guaranteed compressible.

For Type B, the process (step SSST12) is the same as that in the flow shown in FIG. 12. As a single assignment is made and the test pattern is free, this assignment is compressible.

For Type C, like Type A, a set of X-bits that can be concurrently assigned is first identified (CFBS Identification (step SSST13)). Then, the original JP-filling method is utilized to assign these X-bits (step SSST14).

Note that Phase I and CFBS Identification guarantee that the row vector of each newly assigned X-bit in Phase II cannot be spanned by those of the previously and newly assigned bits (with itself excluded). Thus, the “OB Update” process in Phase I simply adds row vectors of the newly assigned bits in Phase II to the orthogonal basis.

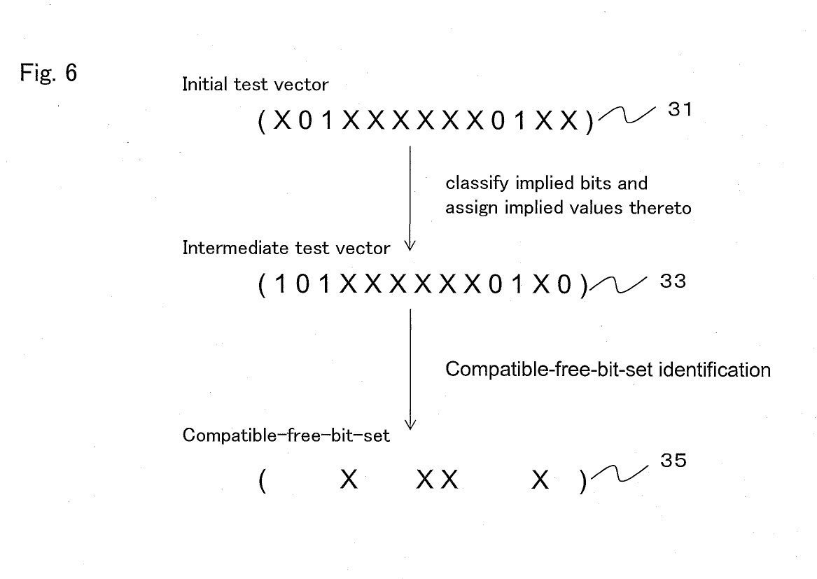

FIG. 6 illustrates an example flow of identifying a compatible-free-bit-set from a test vector by CJP-filling in accordance with the present invention. A given initial test vector 31 includes an X-bit and it is compressible. Here, X-bit is a bit whose value can be either 0 or 1 for fault detection. For the initial test vector 31, in X-classification step SSST2 in FIG. 5, implied bits are classified. Here, an implied bit is a bit whose value is specified for keeping compressibility. And in step SSST3, the implied bits are assigned with their implied values to generate an intermediate test vector 33. For X-bits of PPI-PPO pairs classified as Type A or C in step SSST7 or SSST9, respectively, which are X-bits included in the intermediate test vector 33 (free bits), compatible-free-bits are further classified to identify compatible-free-bit-set (CFBS) 35. Here, compatible-free-bits are bits which belong to a set where logic values can be independently arbitrarily assigned at the same time keeping compressibility. Multi-bit assignments are performed for the identified compatible-free-bit-set 35, which realizes high speed processing.

The following theorem establishes the foundation of the CFBS Identification algorithm.

Theorem 2. A set of free bits can be randomly assigned at the same time and the resulting pattern is still compressible if, for any of the free bits in this set, its row vector cannot be spanned by the union of the orthogonal basis before assignment and the row vectors of the other free bits in this set.

Proof. Denote the set of free X bits by X. Assume that the size of X is q and Rank (Mₛ)=r. The property of X ensures that, after the concurrent random assignments, we have Rank (Mₛ′)=r+q and, as a result, Rank ([Mₛ′|Vₛ′])=r+q. This proves the theorem. Q.E.D.

The CFBS Identification heuristic for type A and C pairs is as follows. These pairs are sorted in ascending order according to the flip-flop weight, i.e., the fanout size. This way, flip-flops with larger weights are considered first as they have more impact on launch noise reduction. The selection process is as follows.

1. Pick the first unprocessed pair in the list as the target pair.

2. If the row vector of the target pair's X-bit cannot be spanned by the current orthogonal basis, the target pair's X-bit is selected and its row vector is added to the orthogonal basis.

3. If not all pairs are processed, go to 1.

The X-bits selected this way can be randomly assigned at the same time. Therefore, the JP-filling methods for type A and C pairs can be employed to concurrently target these selected X-bits.

CFBS Identification further improves the CJP-filling efficiency. The reasons are as follows.

First, CFBS Identification reduces the number of times the loop is executed because it enables multi-assignments. Secondly, the incurred CPU overhead is small because CFBS Identification implicitly classifies the X-bits of the processed pairs and performs “OB Update” for the selected bits—the X-bits that are not selected are implied bits while row vectors of the selected bits have been added to the orthogonal basis. In other words, some of the operations in “OB Update” and “X Classification” are performed in CFBS with a better use model.

The following theorem provides the foundation of the performance analysis.

Theorem 3. Given a compressible test pattern V, the maximum number of times the CJP-filling loop is performed is the number of free variables from ATE minus the size of the orthogonal basis before CJP-filling.

Proof. At the beginning, the rank of Mₛ equals the size of the orthogonal basis before CJP-filling. At the end, the rank of Mₛ, i.e., M, will be smaller than or equal to the number of free variables. Thus, the theorem is proved if we show that the rank of Mₛ increases in each loop. This is true if type B pairs are processed because a single free bit assignment is made. This is also true for type A and C pairs because if q bits are concurrently assigned, the CFBS Identification process ensures that the rank of Mₛ increases by q. This proves the theorem. Q.E.D.

In the following, we compare the performance of the naive flow shown in FIG. 12 and proposed CJP-filling flow shown in FIG. 5. First, their loop run times are about the same. The reason is that the X-bit classification, the CFBS Identification, and the compressibility check are all based on Gaussian Elimination. Second, the number of times the proposed CJP-filling loop is executed is less than the number of free variables (Theorem 3) while the naive CJP-filling executes its loop for about m−1/2 times. Finally, the speed-up factor is about (m−1/2)/1=m/1−0.5. Note that the first term is the decompressor's compression rate.

In the embodiment of the present invention above, a decompressor is shown as an example of the upstream logic circuit. However, the logic circuit may not be necessarily a sequential circuit and may be a combinational circuit. Besides, the upstream logic circuit or the downstream logic circuit may be realized by software.

Besides, in the embodiment of the present invention above, the upstream logic circuit and the downstream logic circuit are physically connected. However, they may be necessarily physically disconnected.

Besides, in the embodiment of the present invention above, step SS1 starts after the output pattern memory unit 23 stores the given output pattern. However, the output pattern memory unit 23 may store the given pattern at other timings if it can store accurately as given.

Besides, in the embodiment of the present invention above, CFBS Identification is performed after X-Classification. However, each process of X-Classification and CFBS Identification may be performed independently.

Besides, in the embodiment of the present invention above, vectors are utilized for fault detection of the logic circuit under test. However, vectors may be utilized for fault diagnosis or design verification of logic circuits.

### DESCRIPTION OF SYMBOLS

SS1 X-Classification step
SS3 Compatible-Free-Bit-Set Identification step
SSST2 X-Classification step
SSST10, 13 Compatible-Free-Bit-Set Identification step

1-6. (canceled)

7. A generation device for generating a new vector from an initial vector to be applied to a logic circuit based on classifying unspecified bits among bits in the initial vector, the unspecified bits being bits whose values are not specified, comprising:
a first classification unit that classifies an unspecified bit as an implied bit if its value is a logic value determined as logic value 0 or 1 relating to logic bits in the initial vector and according to a predetermined condition among bits in the initial vector, the logic bit being a bit whose value is a specified logic value, and classifies an unspecified bit which is not an implied bit as a free bit;
an implied value assignment unit that assigns the logic value determined as 0 or 1 to the implied bit;
a second classification unit that classifies the free bits into pluralities of sets;
a third classification unit that, when a predetermined set among the pluralities of sets is not empty, further classifies the free bits belonging to the predetermined set as compatible free bits if the predetermined condition is satisfied no matter what logic values are independently assigned to the free bits; and
a compatible free bit assignment unit that assigns a logic value 0 or 1 to each compatible free bit,
wherein, if there is an unspecified bit in a vector generated after assignment by the implied value assignment unit and by the compatible free bit assignment unit, the first classification unit newly classifies an unspecified bit as an implied bit if its value is determined as logic value 0 or 1 relating to logic bits in the vector generated and according to the predetermined condition, and newly classifies an unspecified bit which is not the implied bit as a free bit.

8. A classification method for classifying unspecified bits among bits in an initial vector to be applied to a logic circuit, the unspecified bits being bits whose values are not specified, comprising the steps of:
classifying an unspecified bit as an implied bit if its value is a logic value determined as logic value 0 or 1 relating to logic bits in the initial vector and according to a predetermined condition among bits in the initial vector, the logic bit being a bit whose value is a specified logic value, and classifies an unspecified bit which is not an implied bit as a free bit; and
further classifying the free bits as compatible free bits if the free bits belong to a predetermined set where the predetermined condition is satisfied no matter what logic values are independently assigned to the free bits.

9. A generation method performed by a generation device for generating a new vector from an initial vector to be applied to a logic circuit based on classifying unspecified bits among bits in the initial vector, the unspecified bits being bits whose values are not specified, comprising the steps of:
classifying an unspecified bit as an implied bit if its value is a logic value determined as logic value 0 or 1 relating to logic bits in the initial vector and according to a predetermined condition among bits in the initial vector, the logic bit being a bit whose value is a specified logic value, and classifies an unspecified bit which is not an implied bit as a free bit;
assigning the logic value determined as 0 or 1 to the implied bit;
determining whether there is a free bit at a pseudo primary input of a pair of a pseudo primary input and a pseudo primary output (a PPI-PPO pair) or not, and if any, further classifying the free bits at pseudo primary inputs as compatible free bits if the predetermined condition is satisfied no matter what logic values are independently assigned to the free bits at the pseudo primary inputs, and assigning logic values 0 or 1 to the compatible free bits at the same time;
newly classifying, if there is an unspecified bit in a vector generated after assignment to the implied bits and to the compatible free bits, an unspecified bit as an implied bit if its value is a logic value further determined as logic value 0 or 1 relating to logic bits in the vector generated and according to the predetermined condition among bits in the vector generated, and newly classifies an unspecified bit which is not an implied bit as a free bit; and
assigning the logic value further determined to the newly classified implied bit, determining whether there are newly classified free bits at pseudo primary inputs or not, further classifying the newly classified free bits as newly classified compatible free bits, and assigning logic values to the newly classified compatible free bits.

10. A classification method, implemented in a computer, for classifying unspecified bits among bits in an initial vector to be applied to a logic circuit, the unspecified bits being bits whose values are not specified, the classification method comprising the steps of:
classifying an unspecified bit as an implied bit if its value is a logic value determined as logic value 0 or 1 relating to logic bits in the initial vector and according to a predetermined condition among bits in the initial vector, the logic bit being a bit whose value is a specified logic value, and classifies an unspecified bit which is not an implied bit as a free bit; and
further classifying the free bits as compatible free bits if the free bits belong to a predetermined set where the predetermined condition is satisfied no matter what logic values are independently assigned to the free bits.
